(19) United States
(12) Patent Application Publication
(10) Pub. No.: US 2022/0005956 A1
(43) Pub. Date: Jan. 6, 2022

(54) DISPLAY PANEL AND ELECTRONIC DEVICE

(71) Applicant: Shenzhen China Star Optoelectronics Semiconductor Display Technology Co., Ltd., Shenzhen, Guangdong (CN)

(72) Inventors: Yuanpeng CHEN, Shenzhen, Guangdong (CN); Yuanjun HSU, Shenzhen, Guangdong (CN); Zhaosong LIU, Shenzhen, Guangdong (CN)

(21) Appl. No.: 16/651,874

(22) PCT Filed: Feb. 13, 2020
(86) PCT No.: PCT/CN2020/074985

§ 371 Date: Mar. 27, 2020

(30) Foreign Application Priority Data
Jan. 19, 2020 (CN) 202010062240.X

(51) Int. Cl. H01L 29/786

(52) U.S. Cl. CPC H01L 29/78693; H01L 29/78633

(57) ABSTRACT

A display panel and an electronic device are disclosed. The display panel includes a metal oxide semiconductor layer disposed on a substrate. Part of a gate insulating layer is disposed on the metal oxide semiconductor layer. Part of a first metal layer is disposed on the gate insulating layer. The first metal layer includes a gate electrode. A protection layer is disposed on the gate electrode, the gate insulating layer, and the metal oxide semiconductor layer, and the protection layer is made of a metal oxide.

### BACKGROUND OF INVENTION

### 1. Field of Invention

The present invention relates to a technical field of displays, and particularly to, a display panel and an electronic device.

### 2. Related Art

In order to drive display panels such as organic light-emitting diode (OLED) devices, thin-film transistors (TFTs) are required to have a high mobility to generate a sufficient high driving current, and stability of the thin-film transistors also directly affects the OLED display characteristics.

In order to improve the mobility of thin-film transistors, oxide semiconductors are currently used as semiconductor layers in thin-film transistors. However, the oxide semiconductor material tends to be affected by moisture and oxygen, which reduces the stability of TFT devices, and further reduces conductivity of the thin-film transistors.

Therefore, it is imperative to provide a display panel and an electrode device to overcome the above-mentioned problem.

### SUMMARY OF INVENTION

An object of the present invention is to provide a display panel and an electronic device, capable of improving stability and conductive performance of thin-film transistors.

In order to achieve the above-mentioned object, the present invention provides a display panel, comprising a substrate; a metal oxide semiconductor layer disposed on the substrate; a gate insulating layer, wherein part of the gate insulating layer is disposed on the metal oxide semiconductor layer, a first metal layer, where part of the first metal layer is disposed on the gate insulating layer, and the first metal layer comprises a gate electrode; a protection layer disposed on the gate electrode, the gate insulating layer, and the metal oxide semiconductor layer, and made of a metal oxide; a first insulating layer disposed on the protection layer; and a second metal layer disposed on the first insulating layer, and comprising a source electrode and a drain electrode.

The present invention further provides an electronic device comprising the aforementioned display panel.

A display panel and an electronic device of the present invention include a substrate; a metal oxide semiconductor layer disposed on the substrate; a gate insulating layer, wherein part of the gate insulating layer is disposed on the metal oxide semiconductor layer; a first metal layer, where part of the first metal layer is disposed on the gate insulating layer, and the first metal layer includes a gate electrode; a protection layer disposed on the gate electrode, the gate insulating layer, and the metal oxide semiconductor layer, and made of a metal oxide; a first insulating layer disposed on the protection layer; and a second metal layer disposed on the first insulating layer, and including a source electrode and a drain electrode. Because the protection layer is also made of a metal oxide, it can significantly increase protection for the metal oxide semiconductor layer, thereby reducing adverse influence of external moisture and oxygen on oxide materials, and improving stability and conductive performance of thin-film transistors.

### BRIEF DESCRIPTION OF DRAWINGS

FIG. 1 is a schematic structural view of a display panel in accordance with an embodiment of the present invention.

FIG. 2 is another schematic structural view of a display panel in accordance with an embodiment of the present invention.

FIG. 3 is a schematic structural view showing part of a display panel fabricated by a first step to a fourth step of a method for manufacturing the display panel of FIG. 2.

FIG. 4 is a schematic structural view showing part of a display panel fabricated by a fifth step to a sixth step of a method for manufacturing the display panel of FIG. 2.

FIG. 5 is a schematic structural view showing part of a display panel fabricated by a seventh step of a method for manufacturing the display panel of FIG. 2.

### DESCRIPTION OF PREFERRED EMBODIMENTS

The following embodiments are referring to the accompanying drawings for exemplifying specific implementable embodiments of the present invention. Directional terms described by the present invention, such as upper, lower, front, back, left, right, inner, outer, side, etc., are only directions by referring to the accompanying drawings, and thus the used directional terms are used to describe and understand the present invention, but the present invention is not limited thereto.

The terms “first”, “second”, and the like in the description and claims of the present application and the above-mentioned drawings are used to distinguish different objects, rather than describing a specific order. Furthermore, the terms “including” and “having” and any variations thereof are intended to cover non-exclusive inclusion.

Please refer to FIG. 1 showing a schematic structural view of a display panel in accordance with an embodiment of the present invention.

As shown in FIG. 1, the display panel of the embodiment includes a substrate 11, a metal oxide semiconductor layer 14, a gate insulating layer 15, a first metal layer 16, a protection layer 17, a first insulating layer 18, and a second metal layer 19.

The metal oxide semiconductor layer 14 is disposed on the substrate 11. Part of the gate insulating layer 15 is disposed on the metal oxide semiconductor layer 14.

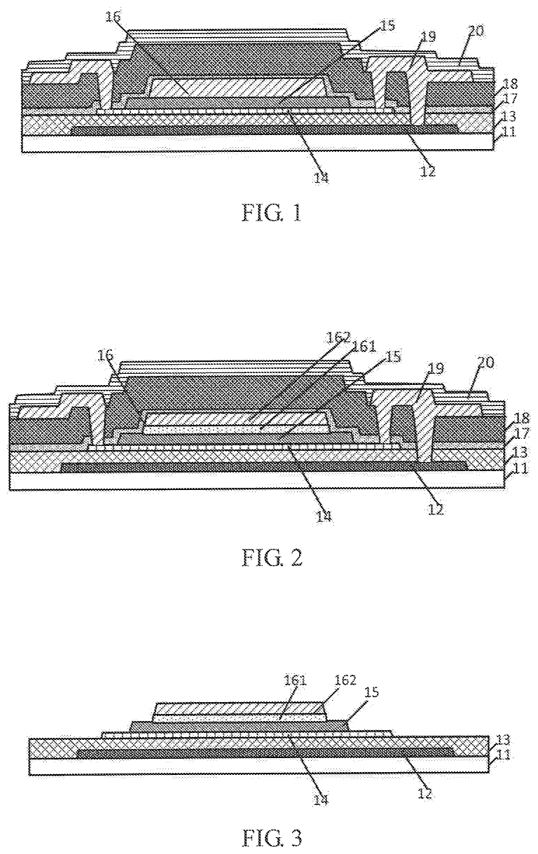

Part of the first metal layer 16 is disposed on the gate insulating layer 15, and the first metal layer 16 includes a gate electrode (not shown). The first metal layer 16 may be a single-layered film. In one embodiment, further referring to FIG. 2, in order to reduce a resistance of the gate electrode, the first metal layer includes a first sub-layer 161 and a second sub-layer 162. The first sub-layer 161 is provided to increase adhesion between the second sub-layer 162 and the gate insulating layer 15. The first sub-layer 161 is made of a material including at least one of molybdenum (Mo), titanium (Ti), and nickel (Ni). In one embodiment, the first sub-layer 161 has a thickness less than a thickness of the second sub-layer 162, and the thickness of the first sub-layer 161 may be between 50 angstroms (Å) and 500 Å. The second sub-layer 162 is made of a material including copper (Cu) or a Cu alloy, and the thickness of the second sub-layer 162 is between 2000-10000 Å. It can be understood that the first metal layer 16 may be made of Cu or a Cu alloy the same as the second metal layer.

The protection layer 17 is disposed on the gate electrode, the gate insulating layer 15, and the metal oxide semiconductor layer 14. The protection layer 17 is made of a metal oxide. In one embodiment, the protection layer 17 is made of a material comprising at least one of aluminum (Al), calcium (Ca), magnesium (Mg), Ti, Mo, and Ni.

The first insulating layer 18 is disposed on the protection layer 17. In one embodiment, the protection layer 17 has a thickness less than a thickness of the first insulating layer 18. The thickness of the protection layer 17 is between 30 Å-500 Å, and the thickness of the first insulating layer 18 is between 3000 Å-10000 Å, wherein the protection layer 17 and the first insulating layer 18 each are provided with a via hole.

The second metal layer 19 is disposed on the first insulating layer 18, and includes a source electrode and a drain electrode. In one embodiment, the second metal layer 19 also includes a first sub-layer and a second sub-layer, wherein the first sub-layer is provided to increase adhesion between the second sub-layer and the first insulating layer 18. The first sub-layer is made of a material including at least one of Mo, Ti, and Ni. In one embodiment, the first sub-layer has a thickness less than a thickness of the second sub-layer, and the thickness of the first sub-layer may be between 50 Å-500 Å. The second sub-layer is made of a material including Cu or a Cu alloy, and the thickness of the second sub-layer is between 2000 Å-10000 Å. It can be understood that the second metal layer 19 may be a single-layered film, and the second metal layer 19 may be made of Cu or a Cu alloy. The source electrode and the drain electrode are connected to the metal oxide semiconductor layer through the via holes.

In addition, the display panel further includes a light shielding layer 12. The light shielding layer 12 is disposed between the substrate 11 and the metal oxide semiconductor layer 14. The light shielding layer 12 covers the metal oxide semiconductor layer 14. In one embodiment, the drain electrode is connected to the light shielding layer 12.

The display panel further includes a buffer layer 13 and a second insulating layer 20. The buffer layer 13 is disposed between the light shielding layer 12 and the metal oxide semiconductor layer 14.

The second insulating layer 20 is disposed on the second metal layer 19.

Since the protection layer 17 provided is also made of a metal oxide, it can significantly increase protection for the metal oxide semiconductor layer 14, thereby reducing adverse influence of external moisture and oxygen on oxide materials, and improving stability and conductive performance of thin-film transistors, as well as enhancing display performance.

A method of manufacturing a display panel includes steps as follows:

S101: fabricating a light shielding layer 12 on a substrate;

For example, as shown in FIG. 3, in one embodiment, a substrate 11 is a glass substrate.

Clean the glass substrate (array glass) and deposit a metal layer (e.g. a single-layered or two-layered metal), and pattern the metal layer using a wet etching process, so that the metal layer is formed into a light shielding layer 12. The light shielding layer 12 may also function as traces, and covers a metal oxide semiconductor layer 14.

S102: fabricating the metal oxide semiconductor layer 14 on the light shielding layer 12.

For example, deposit a buffer layer 13 on the light shielding layer 12 using a plasma enhanced chemical vapor deposition (PECVD) process. The buffer layer 13 may be a single-layered film or a two-layered film, and the buffer layer 13 is made of a material including at least one of silicon nitride (Si₃N₄), silicon dioxide (SiO₂), and silicon oxynitride (SiON). The buffer layer 13 has a thickness between 1000-5000 Å.

Then, an oxide semiconductor material is deposited on the buffer layer 13 and being patterned, so that the oxide semiconductor material is formed into the metal oxide semiconductor layer 14, that is, an active area is formed. The metal oxide semiconductor layer 14 may be made of an amorphous oxide semiconductor, such as at least one of indium-gallium-zinc-oxide (IGZO), indium-tin-zinc-oxide (ITZO), and indium-gallium-zinc-tin-oxide (IGZTO).

The metal oxide semiconductor layer 14 is fabricated through a physical vapor disposition (PVD) process. The metal oxide semiconductor layer 14 has a thickness between 100 Å and 1000 Å.

S103: fabricating a gate insulating layer on the metal oxide semiconductor layer 14.

For example, as shown in FIG. 3, a gate insulating layer (GI) may be deposited through a PECVD process. A gate insulating layer 15 is made of SiOx, wherein an oxygen content can be adjusted by a chemical vapor deposition process (such as PECVD), wherein the gate insulating layer 15 has a thickness between 500 Å-2000 Å. In order to further increase conductivity performance of thin-film transistors, an oxygen content used for the PECVD process can be set according to conductivity parameters of the metal oxide semiconductor layer 14, wherein the conductivity parameters include resistivity or number of atoms of each element in the metal oxide semiconductor layer 14.

S104: fabricating a first metal layer on the gate insulating layer.

For example, further referring to FIGS. 2 and 3, a metal layer is deposited on the gate insulating layer through a PVD process to form a first metal layer. In one embodiment, a first metal layer 16 includes a first sub-layer 161 and a second sub-layer 162. The first sub-layer 161 is provided to increase adhesion between the second sub-layer 162 and the gate insulating layer 15. The first sub-layer 161 is made of a material including at least one of Mo, Ti, and Ni. In one embodiment, the first sub-layer 161 has a thickness less than a thickness of the second sub-layer 162, and the thickness of the first sub-layer 161 may be between 50 Å and 500 Å. The second sub-layer 162 is made of a material including Cu or a Cu alloy, and the thickness of the second sub-layer 162 is between 2000 Å-10000 Å.

The first sub-layer 161 and the second sub-layer 162 can be patterned concurrently during the fabrication process. A patterning process includes steps, such as exposure, development, and etching, etc., wherein a wet etching process can be used for the etching, thereby defining the gate electrode. It can be understood that in other embodiments, the first metal layer 16 may be a single-layered metal.

Then, the gate electrode can be used as an etching pattern for the gate insulating layer. The gate insulating layer is etched, so that the metal oxide semiconductor layer 14 is configured with a channel region exposed to the outside.

S105: forming a protection layer 17 on the gate electrode, the gate insulating layer, and the metal oxide semiconductor layer.

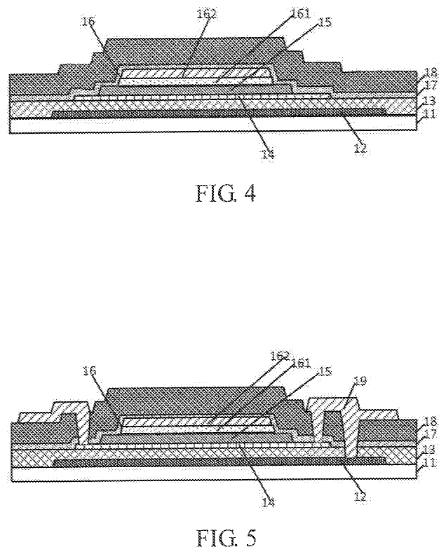

For example, as shown in FIG. 4, an oxide material such as amorphous metal oxide (AMO) is first deposited on the gate electrode, the gate insulating layer 15, and the metal oxide semiconductor layer 14. The protection layer 17 can be made by a preparation process of direct deposition, or the corresponding amorphous metal oxide can first be formed by depositing the corresponding metal material and then adopting annealing oxidation.

The protection layer 17 is made of a material including at least one of Al, Ca, Mg, Ti, Mo, and Ni, and the protection layer 17 has a thickness between 30 Å-500 Å.

S106: forming a first insulating layer 18 on the protection layer 17.

For example, as shown in FIG. 4, an insulating material may be deposited on the protection layer 17 through a PECVD process. The insulating material is made of SiO₂, wherein an oxygen content can be adjusted by the PECVD process. In order to further increase conductivity performance of thin-film transistors, an oxygen content used for a chemical vapor deposition process can be set according to conductivity parameters of the metal oxide semiconductor layer 14, wherein the conductivity parameters include resistivity or number of atoms of each element in the metal oxide semiconductor layer 14. In one embodiment, in order to further increase conductivity performance of the thin-film transistors, the oxygen content can be set according to conductivity parameters of the metal oxide semiconductor layer 14.

The first insulating layer 18 has a thickness between 3000 Å-10000 Å. Then, the protection layer 17 and the first insulating layer 18 may be subjected to a patterning process at the same time to form via holes.

S107: forming a second metal layer 19 on the first insulating layer 18.

As shown in FIG. 5, the second metal layer 19 is formed on the first insulting layer 18. In one embodiment, the second metal layer 19 also includes a first sub-layer and a second sub-layer. the first sub-layer is provided to increase adhesion between the second sub-layer and the first insulating layer 18. The first sub-layer is made of a material including at least one of Mo, Ti, and Ni. In one embodiment, the first sub-layer has a thickness less than a thickness of the second sub-layer, and the thickness of the first sub-layer may be between 50 Å-500 Å. The second sub-layer is made of a material including Cu or a Cu alloy, and the thickness of the second sub-layer is between 2000 Å-10000 Å.

The first sub-layer and the second sub-layer can be patterned concurrently during the fabrication process. A patterning process includes steps, such as exposure, development, and etching, etc., wherein a wet etching process can be used for the etching, thereby defining the source electrode and the drain electrode. It can be understood that in other embodiments, the second metal layer 19 may be a single-layered metal.

S108: forming a second insulating layer 20 on the second metal layer 19.

For example, referring back to FIG. 2, an insulating material is deposited on the second metal layer 19 through a PECVD process. The second insulating layer 20 has a thickness between 1000 Å-5000 Å.

Since the first metal layer 16 and the second metal layer 19 have a second-layered structure, a resistance of the gate electrode or the source/drain electrode can be reduced. Compared to a single-layered metal (such as AL), the resistance is remarkably reduced, thereby satisfying driving demands for higher resolution and larger sized active matrix organic-light emitting diode (AMOLED) panels.

It can be understood that, in other embodiments, only one of the first metal layer 16 or the second metal layer 19 is a two-layered structure.

The present invention also provides an electronic device including any one of the above-mentioned display panels, and the electronic device may be a mobile phone, a tablet computer, or the like.

A display panel and an electronic device of the present invention include a substrate; a metal oxide semiconductor layer disposed on the substrate; a gate insulating layer, wherein part of the gate insulating layer is disposed on the metal oxide semiconductor layer; a first metal layer, where part of the first metal layer is disposed on the gate insulating layer, and the first metal layer includes a gate electrode; a protection layer disposed on the gate electrode, the gate insulating layer, and the metal oxide semiconductor layer, and made of a metal oxide; a first insulating layer disposed on the protection layer; and a second metal layer disposed on the first insulating layer, and including a source electrode and a drain electrode. Because the protection layer is also made of a metal oxide, it can significantly increase protection for the metal oxide semiconductor layer, thereby reducing adverse influence of external moisture and oxygen on oxide materials, and improving stability and conductive performance of thin-film transistors.

Accordingly, although the present invention has been disclosed as a preferred embodiment, it is not intended to limit the present invention. Those skilled in the art without departing from the spirit and scope of the present invention may make various changes or modifications, and thus the scope of the present invention should be after the appended claims and their equivalents.

What is claimed is:

1. A display panel, comprising:
a substrate;
a metal oxide semiconductor layer disposed on the substrate;
a gate insulating layer, wherein part of the gate insulating layer is disposed on the metal oxide semiconductor layer;
a first metal layer, where part of the first metal layer is disposed on the gate insulating layer, and the first metal layer comprises a gate electrode;
a protection layer disposed on the gate electrode, the gate insulating layer, and the metal oxide semiconductor layer, and made of a metal oxide;
a first insulating layer disposed on the protection layer; and
a second metal layer disposed on the first insulating layer, and comprising a source electrode and a drain electrode.

2. The display panel of claim 1, wherein the protection layer is made of an amorphous metal oxide.

3. The display panel of claim 2, wherein the protection layer is made of a material comprising at least one of aluminum (Al), calcium (Ca), magnesium (Mg), titanium (Ti), molybdenum (Mo), and nickel (Ni).

4. The display panel of claim 1, wherein the protection layer has a thickness less than a thickness of the first insulating layer.

5. The display panel of claim 4, wherein the thickness of the protection layer is between 30 angstroms (Å) and 500 Å, and the thickness of the first insulating layer is between 3000 Å and 10000 Å.

6. The display panel of claim 1, wherein each of the first metal layer and/or the second metal layer comprises a first sub-layer and a second sub-layer.

7. The display panel of claim 6, wherein the first sub-layer is made of a material comprising at least one of Mo, Ti, and Ni, and the second sub-layer is made of copper.

8. The display panel of claim 6, wherein the first sub-layer has a thickness less than a thickness of the second sub-layer.

9. The display panel of claim 8, wherein the thickness of the first sub-layer is between 50 Å and 500 Å, and the thickness of the second sub-layer is between 2000 Å and 10000 Å.

10. The display panel of claim 1, wherein each of the gate insulating layer and the first insulating layer is fabricated through a chemical vapor deposition process, wherein the chemical vapor deposition process is implemented with an oxygen content set according to conductivity parameters of the metal oxide semiconductor layer.

11. The display panel of claim 1, further comprising a light shielding layer disposed between the substrate and the metal oxide semiconductor layer, wherein the light shielding layer covers the metal oxide semiconductor layer.

12. An electronic device, comprising a display panel, wherein the display panel comprises:
a substrate;
a metal oxide semiconductor layer disposed on the substrate;
a gate insulating layer, wherein part of the gate insulating layer is disposed on the metal oxide semiconductor layer;
a first metal layer, where part of the first metal layer is disposed on the gate insulating layer, and the first metal layer comprises a gate electrode;
a protection layer disposed on the gate electrode, the gate insulating layer, and the metal oxide semiconductor layer, and made of a metal oxide;
a first insulating layer disposed on the protection layer; and
a second metal layer disposed on the first insulating layer, and comprising a source electrode and a drain electrode.

13. The electronic device of claim 12, wherein the protection layer is made of an amorphous metal oxide.

14. The electronic device of claim 13, wherein the protection layer is made of a material comprising at least one of aluminum (Al), calcium (Ca), magnesium (Mg), titanium (Ti), molybdenum (Mo), and nickel (Ni).

15. The electronic device of claim 12, wherein the protection layer has a thickness less than a thickness of the first insulating layer.

16. The electronic device of claim 15, wherein the thickness of the protection layer is between 30 angstroms (Å) and 500 Å, and the thickness of the first insulating layer is between 3000 Å and 10000 Å.

17. The electronic device of claim 12, wherein each of the first metal layer and/or the second metal layer comprises a first sub-layer and a second sub-layer.

18. The electronic device of claim 17, wherein the first sub-layer is made of a material comprising at least one of Mo, Ti, and Ni, and the second sub-layer is made of copper.

19. The electronic device of claim 17, wherein the first sub-layer has a thickness less than a thickness of the second sub-layer.

20. The electronic device of claim 12, wherein each of the gate insulating layer and the first insulating layer is fabricated through a chemical vapor deposition process, wherein the chemical vapor deposition process is implemented with an oxygen content set according to conductivity parameters of the metal oxide semiconductor layer.
